(19) United States
(12) Patent Application Publication
(10) Pub. No.: US 2026/0271546 A1
(43) Pub. Date: Sep. 10, 2026

(54) DISPLAY DEVICE AND ELECTRONIC DEVICE

(71) Applicant: Samsung Display Co., Ltd., Yongin-si (KR)

(72) Inventors: Jun Hyun PARK, Yongin-si (KR); Hwa Rang LEE, Yongin-si (KR); Na Hyeon CHA, Yongin-si (KR)

(73) Assignee: Samsung Display Co., Ltd., Yongin-si (KR)

(21) Appl. No.: 19/333,619

(22) Filed: Sep. 19, 2025

(30) Foreign Application Priority Data
Mar. 5, 2025 (KR) 10-2025-0028175
Apr. 30, 2025 (KR) 10-2025-0056814

(51) Int. Cl. H10K 59/123; G02B 27/01; H10K 59/131

(52) U.S. Cl. CPC H10K 59/123; H10K 59/131; G02B 27/0172

(57) ABSTRACT

A display device includes a display panel in which a pixel is disposed. The pixel includes: a light emitting element connected between a driving voltage line and a common voltage line; a first transistor connected between the driving voltage line and an anode electrode of the light emitting element; a second transistor connected between a data line and a first node; a first capacitor connected between a gate electrode of the first transistor and the first node; and a second capacitor connected between the first node and the anode electrode of the light emitting element.

### CROSS-REFERENCE TO RELATED APPLICATIONS

This application is based on and claims priority under 35 U.S.C. § 119 to Korean Patent Application Nos. 10-2025-0028175, filed on Mar. 5, 2025, and 10-2025-0056814, filed on Apr. 30, 2025, in the Korean Intellectual Property Office, the disclosures of which are incorporated by reference herein in their entireties.

### BACKGROUND

### 1. Field

The present disclosure relates to a display device, and more particularly, to a display device and an electronic device in which a compensation error may be minimized and power consumption may be reduced.

### 2. Description of Related Art

An organic light emitting display device includes a display element whose luminance is changed by current, for example, an organic light emitting diode.

### SUMMARY

Aspects of the present disclosure provide a display device and an electronic device in which a compensation error may be minimized and power consumption may be reduced.

According to an aspect of the present disclosure, a display device includes a display panel in which a pixel is disposed. The pixel includes: a light emitting element connected between a driving voltage line and a common voltage line; a first transistor connected between the driving voltage line and an anode electrode of the light emitting element; a second transistor connected between a data line and a first node; a first capacitor connected between a gate electrode of the first transistor and the first node; and a second capacitor connected between the first node and the anode electrode of the light emitting element.

According to an aspect of the present disclosure, an electronic device includes a display device including a display panel in which a pixel is disposed. The pixel includes: a light emitting element connected between a driving voltage line and a common voltage line; a first transistor connected between the driving voltage line and an anode electrode of the light emitting element; a second transistor connected between a data line and a first node; a first capacitor connected between a gate electrode of the first transistor and the first node; and a second capacitor connected between the first node and the anode electrode of the light emitting element.

According to embodiments of the present disclosure, the compensation error of the display device and the electronic device may be minimized, and the power consumption thereof may be reduced.

For example, according to an embodiment, since the first capacitor (where the threshold voltage of the first transistor is stored) and the source electrode of the first transistor are separated from each other by the second capacitor, a fluctuation rate of the threshold voltage of the first transistor (e.g., the threshold voltage of the first transistor stored in the first capacitor) may be minimized when a data voltage is input. Therefore, the compensation error of the threshold voltage may be removed.

Furthermore, according to an embodiment, since the first capacitor and the second capacitor are connected in series between the gate electrode of the first transistor and the source electrode of the first transistor, a transmission rate of the data voltage may be increased. Accordingly, the power consumption of the display device may be reduced.

The effects and the advantages of the present disclosure are not limited to the above-described effects and the advantages and other effects and the advantages which are not described herein will become apparent to those skilled in the art from the following description.

### BRIEF DESCRIPTION OF DRAWINGS

The above and other aspects and features of the present disclosure will become more apparent by describing in detail example embodiments thereof with reference to the attached drawings, in which:

FIG. 1 illustrates a display device according to an embodiment;

FIG. 2 illustrates a driving operation of the display device of FIG. 1;

FIG. 3 is a circuit diagram of a pixel according to an embodiment;

FIG. 4 is a timing diagram of a first emission control signal, a second emission control signal, a reset gate signal, a write gate signal, and an initialization gate signal of FIG. 3 in an address scan section;

FIG. 5 is a timing diagram of the first emission control signal, the second emission control signal, the reset gate signal, the write gate signal, and the initialization gate signal of FIG. 3 in a self-scan section;

FIG. 6 illustrates an operation of the display device of FIG. 3 in a first section of the address scan section of FIG. 4;

FIG. 7 illustrates an operation of the display device of FIG. 3 in a second section of the address scan section of FIG. 4;

FIG. 8 illustrates an operation of the display device of FIG. 3 in a third section of the address scan section of FIG. 4;

FIG. 9 illustrates an operation of the display device of FIG. 3 in a fourth section of the address scan section of FIG. 4;

FIG. 10 illustrates an operation of the display device of FIG. 3 in a fifth section of the self-scan section of FIG. 5;

FIG. 11 illustrates an operation of the display device of FIG. 3 in a sixth section of the self-scan section of FIG. 5;

FIG. 12 is a circuit diagram of a pixel according to an embodiment;

FIG. 13 is a circuit diagram of a pixel according to an embodiment;

FIG. 14 illustrates an electronic device according to an embodiment; and

FIGS. 15, 16, and 17 illustrate electronic devices according to various embodiments.

### DETAILED DESCRIPTION

The present disclosure is described more fully hereinafter with reference to the accompanying drawings, in which preferred embodiments of the disclosure are shown. This disclosure may, however, be embodied in different forms. This disclosure is not be construed as limited to the embodiments set forth herein. Rather, these embodiments are provided so that this disclosure will be thorough and complete, and will fully convey the scope of the disclosure to those skilled in the art.

When a layer is referred to as being “on” another layer or substrate, they layer may be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. The terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments may be practiced individually or in combination.

Hereinafter, specific example embodiments will be described with reference to the accompanying drawings.

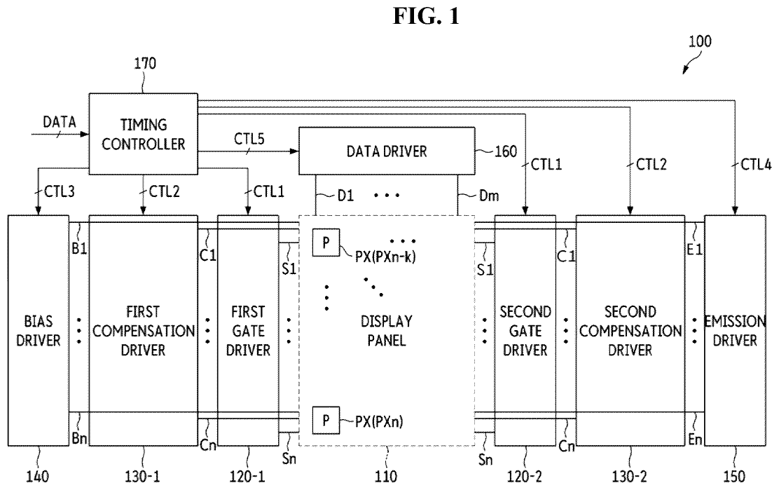

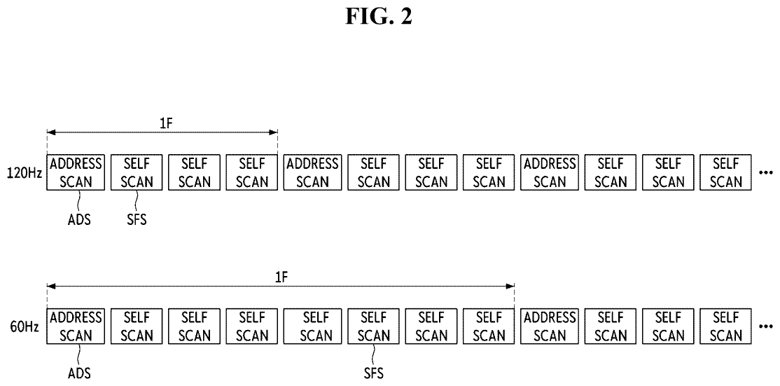

FIG. 1 illustrates a display device according to an embodiment and FIG. 2 illustrates a driving operation of the display device of FIG. 1.

Referring to FIG. 1, a display device 100 may include a display panel 110, a first gate driver 120-1, a second gate driver 120-2, a first compensation driver 130-1, a second compensation driver 130-2, a bias driver 140, an emission driver 150, a data driver 160, and a timing controller 170. In this case, the display device 100 may display images at various driving frequencies depending on driving conditions. For example, the display device 100 may display images at various driving frequencies of 1 Hz to 120 Hz (i.e., a frame rate of a panel driving frame is 1 Hz to 120 Hz). The display device 100 may be, but is not limited to, an organic light emitting display device or a quantum dot light emitting display device.

The display panel 110 may include a plurality of pixels PX. For example, the pixels PX may include a red pixel, a green pixel, and a blue pixel. In this case, each of the pixels PX may be connected to a gate line Sj (where j is an integer greater than or equal to 1 and less than or equal to n) that transmits a gate signal, a compensation line Cj that transmits a compensation signal, a bias line Bj that transmits a bias signal, and a light emitting line Ej that transmits a light emitting signal.

As in the example illustrated in FIG. 2, each of the pixels PX may perform one address scan operation (or display scan operation; for example, an operation of receiving a data voltage to emit light from (or light up) a light emitting element) and at least one self-scan operation (e.g., an operation of changing characteristics of a driving transistor (e.g., a first transistor T1 to be described later) of the pixel). According to an embodiment, each of the pixels PX may have a so-called 8T-1C structure including eight transistors and one capacitor, but is not limited thereto.

As illustrated in FIG. 1, the first and second gate drivers 120-1 and 120-2 (the first gate driver 120-1 and the second gate driver 120-2) may be disposed at both sides of the display panel 110 and the first and second compensation drivers 130-1 and 130-2 (the first compensation driver 130-1 and the second compensation driver 130-2) may also be disposed at both sides of the display panel 110. The bias driver 140 may be disposed at one side of the display panel 110 (e.g., a left side of the display panel 110 in FIG. 1). The emission driver 150 may also be disposed at one side of the display panel 110 (e.g., a right side of the display panel 110 in FIG. 1).

The first and second gate drivers 120-1 and 120-2 may be connected to the display panel 110 through gate lines S1, S2, . . . , and Sn extending in a first direction. The first and second gate drivers 120-1 and 120-2 may apply a gate signal to the display panel 110 through the gate lines S1, S2, . . . , and Sn extending in the first direction. Since the first and second gate drivers 120-1 and 120-2 are disposed at both sides of the display panel 110 in the first direction, and apply the gate signal from both sides of the display panel 110, there may be no deviation in the falling time and/or rising time of the gate signal depending on a position of the pixel PX within the display panel 110. In this way, the display device 100 includes the first and second gate drivers 120-1 and 120-2 disposed at both sides of the display panel 110 in the first direction, thereby preventing a phenomenon of luminance unevenness caused by deviation in the falling time and/or rising time of the gate signal depending on the position of the pixel PX within the display panel 110.

The first and second compensation drivers 130-1 and 130-2 may be connected to the display panel 110 through compensation lines C1, C2, . . . , and Cn extending in the first direction. The first and second compensation drivers 130-1 and 130-2 may apply a compensation signal to the display panel 110 through the compensation lines C1, C2, . . . , and Cn extending in the first direction. In this case, since the first and second compensation drivers 130-1 and 130-2 are disposed at both sides of the display panel 110 in the first direction, and apply the compensation signal from both sides of the display panel 110, there may be no deviation in the falling time and/or rising time of the compensation signal depending on the position of the pixel PX within the display panel 110. In this way, the display device 100 includes the first and second compensation drivers 130-1 and 130-2 disposed at both sides of the display panel 110 in the first direction, thereby preventing a phenomenon of luminance unevenness caused by deviation in the falling time and/or rising time of the compensation signal depending on the position of the pixel PX within the display panel 110.

The bias driver 140 may be connected to the display panel 110 through bias lines B1, B2, . . . , and Bn extending in the first direction. The bias driver 140 may apply a bias signal to the display panel 110 through bias lines B1, B2,. . . , and Bn extending in the first direction. In this case, the bias driver 140 may be disposed at one side of the display panel 110 in the first direction (i.e., the left side of the display panel 110 in FIG. 1).

The emission driver 150 may be connected to the display panel 110 through emission lines E1, E2, . . . , and En extending in the first direction. The emission driver 150 may a light emitting signal to the display panel 110 through emission lines E1, E2, . . . , and En extending in the first direction. In this case, the emission driver 150 may be disposed at one side of the display panel 110 in the first direction (i.e., the right side of the display panel 110 in FIG. 1). In general, the falling time and/or rising time of the gate signal applied to the pixel PX and the falling time and/or rising time of the compensation signal applied to the pixel PX have a relatively large effect on the luminance of the pixel PX, whereas the falling time and/or rising time of the bias signal applied to the pixel PX and the falling time and/or rising time of the light emitting signal EM applied to the pixel PX have a relatively small effect on the luminance of the pixel PX. Accordingly, the bias driver 140 and the emission driver 150 may be disposed only at one side of the display panel 110.

The display panel 110 may be connected to the data driver 160 through data lines D1, D2, . . . , and Dm extending in a second direction intersecting the first direction. The data driver 160 may provide a data voltage (or data signal) to the display panel 110 through the data lines D1, D2, . . . , and Dm extending in the second direction intersecting the first direction. For example, as illustrated in FIG. 2, the data driver 160 may apply the data voltage (or data signal) to the display panel 110 in an address scan section ADS in which the pixels PX perform an address scan operation, and may not apply the data voltage (or data signal) to the display panel 110 in a self-scan section SFS in which the pixels PX perform a self-scan operation.

The timing controller 170 may generate a plurality of control signals CTL1, CTL2, CTL3, CTL4, and CTL5 to control the first gate driver 120-1, the second gate driver 120-2, the first compensation driver 130-1, the second compensation driver 130-2, the bias driver 140, the emission driver 150, and the data driver 160. The timing controller 170 may receive image data DATA from an external component (e.g., a graphic processing unit (GPU) or the like) through a selected interface, perform selected processing (e.g., luminance compensation, deterioration compensation, etc.) on the image data DATA, and provide the image data to the data driver 160. For example, as illustrated in FIG. 2, the timing controller 170 may perform one address scan section ADS and at least one self-scan section SFS at the driving frequency of the display panel 110 (e.g., 120 Hz or 60 Hz in FIG. 2). In an embodiment, when the driving frequency of the display panel 110 is 120 Hz, one panel driving frame 1F may include one address scan section ADS and three self-scan sections SFS, and when the driving frequency of the display panel 110 is 60 Hz, one panel driving frame 1F may include one address scan section ADS and seven self-scan sections SFS. In this case, the timing controller 170 may respond to a change in the driving frequency of the display panel 110 (i.e., a change in a frame rate of the panel driving frame or a change in a driving time of the panel driving frame) by controlling the number of self-scan sections SFS.

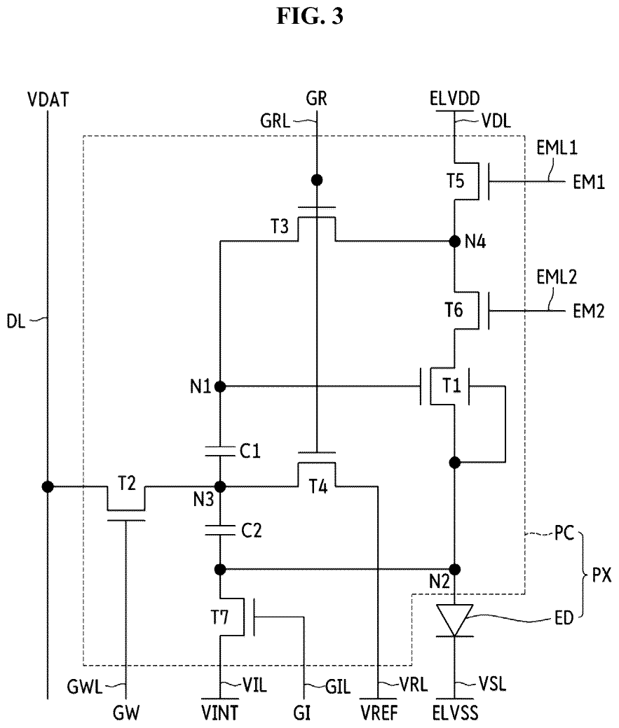

FIG. 3 is a circuit diagram of a pixel PX according to an embodiment.

A pixel PX may be connected to a write gate line GWL, a reset gate line GRL, an initialization gate line GIL, a first emission line EML1, a second emission line EML2, a data line DL, a driving voltage line VDL, a common voltage line VSL, an initialization voltage line VIL, and a reference voltage line VRL.

The pixel PX may include a pixel circuit PC and a light emitting element ED connected to the pixel circuit PC. The pixel circuit PC may include a first transistor T1, a second transistor T2, a third transistor T3, a fourth transistor T4, a fifth transistor T5, a sixth transistor T6, a seventh transistor T7, a first capacitor C1, and a second capacitor C2.

The first transistor T1 may include a gate electrode, a source electrode, and a drain electrode. The first transistor T1 may control a source-drain current (e.g., a driving current) according to a data voltage applied to the gate electrode thereof. The driving current flowing through a channel region of the first transistor T1 may be proportional to a square of a difference between a voltage between the source electrode and the gate electrode of the first transistor T1 and a threshold voltage. According to an embodiment, the first transistor T1 may further include an opposite gate electrode supplied with a driving voltage ELVDD. The opposite gate electrode of the first transistor T1 may be disposed to oppose the gate electrode of the first transistor T1 with an active layer interposed therebetween. The opposite gate electrode of the first transistor T1 may be connected to the source electrode of the first transistor T1. The gate electrode of the first transistor T1 may be electrically connected to a first node N1, the opposite gate electrode of the first transistor T1 may be electrically connected to a second node N2, the drain electrode of the first transistor T1 may be electrically connected to a source electrode of the sixth transistor T6, and the source electrode of the first transistor T1 may be electrically connected to the second node N2.

The second transistor T2 may be turned on by a write gate signal GW from the write gate line GWL and electrically connect the data line DL and a third node N3. A gate electrode of the second transistor T2 may be electrically connected to the write gate line GWL, a drain electrode of the second transistor T2 may be electrically connected to the data line DL, and a source electrode of the second transistor T2 may be electrically connected to the third node N3.

The third transistor T3 may be turned on by a reset gate signal GR from the reset gate line GRL and electrically connect the first node N1 and a fourth node N4. A gate electrode of the third transistor T3 may be electrically connected to the reset gate line GRL, a drain electrode of the third transistor T3 may be electrically connected to the fourth node N4, and a source electrode of the third transistor T3 may be electrically connected to the first node N1.

The fourth transistor T4 may be turned on by the reset gate signal GR from the reset gate line GRL and electrically connect the third node N3 and the reference voltage line VRL. A gate electrode of the fourth transistor T4 may be electrically connected to the reset gate line GRL, a drain electrode of the fourth transistor T4 may be electrically connected to the third node N3, and a source electrode of the fourth transistor T4 may be electrically connected to the reference voltage line VRL. The reference voltage line VRL may transmit a reference voltage VREF.

The fifth transistor T5 may be turned on by a first emission control signal EM1 of the first emission control line EML1 and electrically connect the driving voltage line VDL and the fourth node N4. A gate of the fifth transistor T5 may be electrically connected to the first emission control line EML1, a drain electrode of the fifth transistor T5 may be electrically connected to the driving voltage line VDL, and a source electrode of the fifth transistor T5 may be electrically connected to the fourth node N4. The driving voltage line VDL may transmit a driving voltage ELVDD.

The sixth transistor T6 may be turned on by a second emission control signal EM2 from the second emission control line EML2 and electrically connect the fourth node N4 and the drain electrode of the first transistor T1. A gate electrode of the sixth transistor T6 may be electrically connected to the second emission control line EML2, a drain electrode of the sixth transistor T6 may be electrically connected to the fourth node N4, and a source electrode of the sixth transistor T6 may be electrically connected to the drain electrode of the first transistor T1.

The seventh transistor T7 may be turned on by an initialization gate signal GI from the initialization gate line GIL and electrically connect the second node N2 and the initialization voltage line VIL. A gate electrode of the seventh transistor T7 may be electrically connected to the initialization gate line GIL, a drain electrode of the seventh transistor T7 may be electrically connected to the second node N2, and a source electrode of the seventh transistor T7 may be electrically connected to the initialization voltage line VIL. The initialization voltage line VIL may transmit an initialization voltage VINT.

When the fifth transistor T5, the sixth transistor T6, and the first transistor T1 are all turned on, the driving current may be supplied to the light emitting element ED.

According to an embodiment, the gate electrode of the sixth transistor T6 included in the pixel PX of FIG. 3 and a gate electrode of a fifth transistor T5 (or a sixth transistor T6) of a pixel different from the pixel may be connected together to the same emission control line. For example, when the pixel PX of FIG. 3 is defined as an n-th pixel (e.g., PXn in FIG. 1), and a pixel driven before the n-th pixel PXn is defined as an n-k-th pixel (e.g., PXn-5 in FIG. 1), the gate electrode of the sixth transistor T6 of the n-th pixel PXn and a gate electrode of a fifth transistor T5 (or a sixth transistor T6) of the n-k-th pixel PXn-k may be connected together to the same emission control line (e.g., the second emission control line EML2). Here, k is a natural number. For example, k may be 6. In this case, the gate electrode of the sixth transistor T6 of the n-th pixel PXn and the gate electrode of the fifth transistor T5 (or the sixth transistor T6) of the n-6-th pixel may be connected together to the second emission control line EML2. Accordingly, the number of emission control lines may be reduced. In another embodiment, the above-described k may be greater than 6.

Each of the first transistor T1, the second transistor T2, the third transistor T3, the fourth transistor T4, the fifth transistor T5, the sixth transistor T6, and the seventh transistor T7 described above may be an n-type transistor including an oxide-based active layer. The transistor including the oxide-based active layer may have a coplanar structure in which a gate electrode is disposed thereon. The transistor including the oxide-based active layer may output a current flowing into a drain electrode thereof to a source electrode thereof based on a gate high voltage applied to the gate electrode thereof.

The first capacitor C1 may be electrically connected between the third node N3 and the first node N1. For example, a first electrode of the first capacitor C1 may be electrically connected to the third node N3, and a second electrode of the first capacitor C1 may be electrically connected to the first node N1.

The second capacitor C2 may be electrically connected between the third node N3 and the second node N2. For example, a first electrode of the second capacitor C2 may be electrically connected to the third node N3, and a second electrode of the second capacitor C2 may be electrically connected to the second node N2.

The light emitting element ED may emit light by receiving the driving current. The amount of light emission or luminance of the light emitting element ED may be proportional to the magnitude of the driving current.

The light emitting element ED may be an organic light emitting diode including a first electrode (e.g., a pixel electrode or an anode electrode), a second electrode (e.g., a common electrode or a cathode electrode), and an organic light emitting layer disposed between the first electrode and the second electrode. As another example, the light emitting element ED may be an inorganic light emitting element including a first electrode, a second electrode, and an inorganic semiconductor disposed between the first electrode and the second electrode. As still another example, the light emitting element ED may be a quantum dot light emitting element including a first electrode, a second electrode, and a quantum dot light emitting layer disposed between the first electrode and the second electrode. As still another example, the light emitting element ED may be a micro light emitting diode.

The first electrode of the light emitting element ED may be electrically connected to the second node N2. The first electrode of the light emitting element ED may be connected to the source electrode of the first transistor T1 and the opposite gate electrode of the first transistor T1 through the second node N2. The second electrode of the light emitting element ED may be connected to the common voltage line VSL. The second electrode of the light emitting element ED may receive a common voltage ELVSS (e.g., a low potential voltage) from the common voltage line VSL.

The driving voltage ELVDD, the common voltage ELVSS, the initialization voltage VINT, and the reference voltage VREF may each be a direct current voltage. Here, the driving voltage ELVDD may be a positive polarity direct current voltage, and the common voltage ELVSS, the initialization voltage VINT, and the reference voltage VREF may each be a negative polarity direct current voltage.

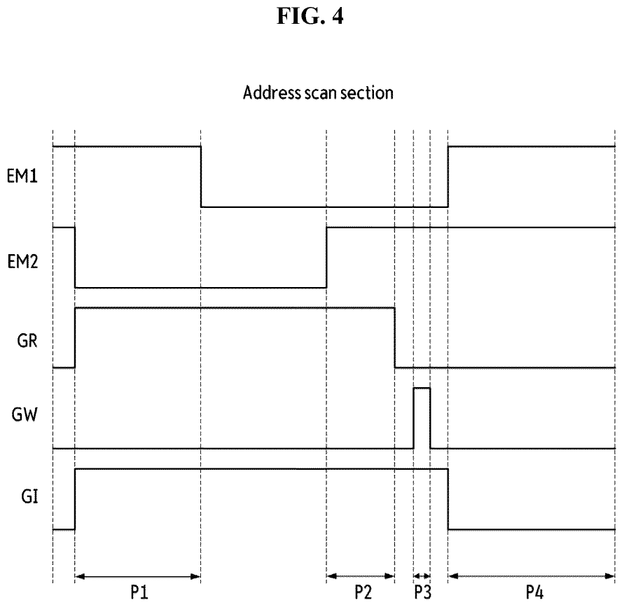

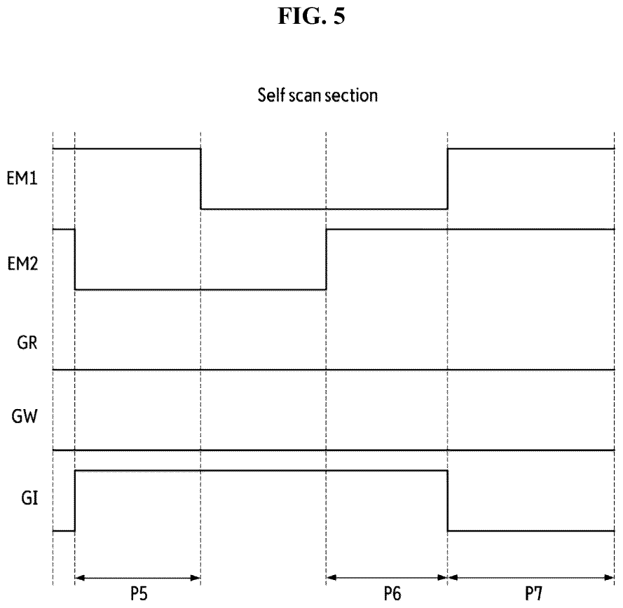

FIG. 4 is a timing diagram of a first emission control signal EM1, a second emission control signal EM2, a reset gate signal GR, a write gate signal GW, and an initialization gate signal GI of FIG. 3 in an address scan section ADS. In addition, FIG. 5 is a timing diagram of a first emission control signal EM1, a second emission control signal EM2, a reset gate signal GR, a write gate signal GW, and an initialization gate signal GI of FIG. 3 in a self-scan section SFS.

Referring to FIG. 4, the address scan section ADS may include a first section P1, a second section P2, a third section P3, and a fourth section P4. In addition, referring to FIG. 5, the self-scan section SFS may include a fifth section P5, a sixth section P6, and a seventh section P7.

The first emission control signal EM1, the second emission control signal EM2, the reset gate signal GR, the write gate signal GW, and the initialization gate signal GI may each have an active level or an inactive level for each preset section of the address scan section ADS and the self-scan section SFS. Here, the active level of each signal described above may mean a voltage level that may turn on the corresponding transistor to which the corresponding signal is applied. In other words, the signal of the active level may have a value greater than a threshold voltage of the corresponding transistor. For example, when the corresponding transistor is an n-type transistor, the active level of the signal applied to the gate electrode of the corresponding transistor may mean a high level (e.g., a positive polarity level or a high voltage level).

The non-active level of each signal may mean a voltage level that may turn off the corresponding transistor. In other words, the signal of the non-active level may have a value smaller than the threshold voltage of the corresponding transistor. For example, when the corresponding transistor is an n-type transistor, the non-active level of the signal applied to the gate electrode of the corresponding transistor may mean a low level (e.g., a negative polarity level or a low voltage level).

In an embodiment, when the corresponding transistor is a p-type transistor, the active level of the signal applied to the gate electrode of the corresponding transistor may mean a low level (e.g., a negative polarity level or a low voltage level), and the non-active level of the signal applied to the gate electrode of the corresponding transistor may mean a high level (e.g., a positive polarity level or a high voltage level).

In the first section P1 of the address scan section ADS, the first emission control signal EM1, the reset gate signal GR, and the initialization gate signal GI may each have an active level. In the first section P1, the second emission control signal EM2 and the write gate signal GW may each have a non-active level.

In the second section P2 of the address scan section ADS, the second emission control signal EM2, the reset gate signal GR, and the initialization gate signal GI may each have an active level. In the second section P2, the first emission control signal EM1 the write gate signal GW may each have a non-active level.

In the third section P3 of the address scan section ADS, the second emission control signal EM2, the write gate signal GW, and the initialization gate signal GI may each have an active level. In the third section P3, the first emission control signal EM1 the reset gate signal GR may each have a non-active level. In addition, in the third section P3, the data voltage may be applied to the data line.

In the fourth section P4 of the address scan section ADS, the first emission control signal EM1 and the second emission control signal EM2 may each have an active level. In the fourth section P4, the reset gate signal GR and the initialization gate signal GI may each have a non-active level.

In the fifth section P5 of the self-scan section SFS, the first emission control signal EM1 and the initialization gate signal GI may each have an active level. In the fifth section P5, the second emission control signal EM2, the reset gate signal GR, and the write gate signal GW may each have a non-active level.

In the sixth section P6 of the self-scan section SFS, the second emission control signal EM2 and the initialization gate signal GI may each have an active level. In the sixth section P6, the first emission control signal EM1, the reset gate signal GR, and the write gate signal GW may each have a non-active level.

In the seventh section P7 of the self-scan section SFS, the first emission control signal EM1 and the second emission control signal EM2 may each have an active level. In the seventh section P7, the reset gate signal GR, the write gate signal GW, and the initialization gate signal GI may each have a non-active level.

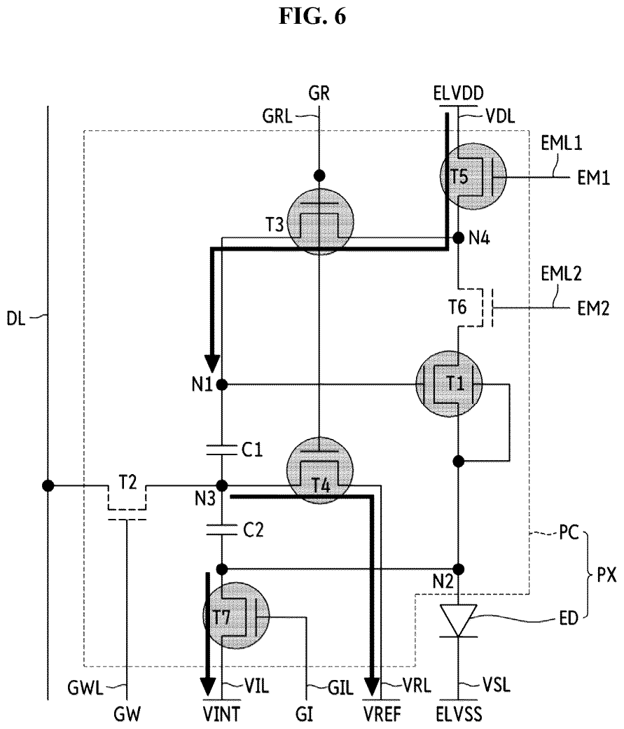

An operation of the display device 100 in the address scan section ADS and self-scan section SFS according to an embodiment is described as follows with reference to FIGS. 6 to 11. In FIGS. 6 to 11, transistors surrounded by a dotted circle are transistors in a turned-on state, and transistors indicated by a dotted line are transistors in a turned-off state.

First, an operation of the display device 100 in the first section P1 of the address scan section ADS is described as follows with reference to FIGS. 4 and 6.

FIG. 6 illustrates an operation of the display device 100 of FIG. 3 in the first section P1 of the address scan section ADS of FIG. 4.

In the first section P1, a reset gate signal GR of an active level may be applied to the gate electrode of the third transistor T3 and the gate electrode of the fourth transistor T4, respectively, through the reset gate line GRL. Accordingly, the third transistor T3 and the fourth transistor T4 may each be turned on.

In the first section P1, a first emission control signal EM1 of an active level may be applied to the gate electrode of the fifth transistor T5 through the first emission control line EML1. Accordingly, the fifth transistor T5 may be turned on.

In the first section P1, an initialization gate signal GI of an active level may be applied to the gate electrode of the seventh transistor T7 through the initialization gate line GIL. Accordingly, the seventh transistor T7 may be turned on.

In the first section P1, a write gate signal GW of a non-active level may be applied to the gate electrode of the second transistor T2 through the write gate line GWL. Accordingly, the second transistor T2 may be turned off.

In the first section P1, a second emission control signal EM2 of a non-active level may be applied to the gate electrode of the sixth transistor T6 through the second emission control line EML2. Accordingly, the sixth transistor T6 may be turned off.

As described above, as the third transistor T3 and the fifth transistor T5 are each turned on, the driving voltage line VDL, the fourth node N4, and the first node N1 may be electrically connected. Accordingly, the driving voltage ELVDD is applied to each of the fourth node N4 and the first node N1, so that a voltage of the fourth node N4 and a voltage of the first node N1 may each be initialized to the driving voltage ELVDD. In this case, the first transistor T1 connected to the first node N1 through the gate electrode may be turned on by the driving voltage ELVDD applied to the first node N1.

As described above, as the fourth transistor T4 is turned on, the reference voltage line VRL and the third node N3 may be electrically connected. Accordingly, the reference voltage VREF is applied to the third node N3, so that a voltage of the third node N3 may be initialized to the reference voltage VREF.

As described above, as the seventh transistor T7 is turned on, the initialization voltage line VIL and the second node N2 may be electrically connected. Accordingly, the initialization voltage VINT is applied to the second node N2, so that a voltage of the second node N2 may be initialized to the initialization voltage VINT.

Therefore, in the first section P1, the voltage of the gate electrode of the first transistor T1, the voltage of the opposite gate electrode of the first transistor T1, the voltage of the source electrode of the first transistor T1, the voltage of the first capacitor C1, and the voltage of the second capacitor C2 may each be initialized.

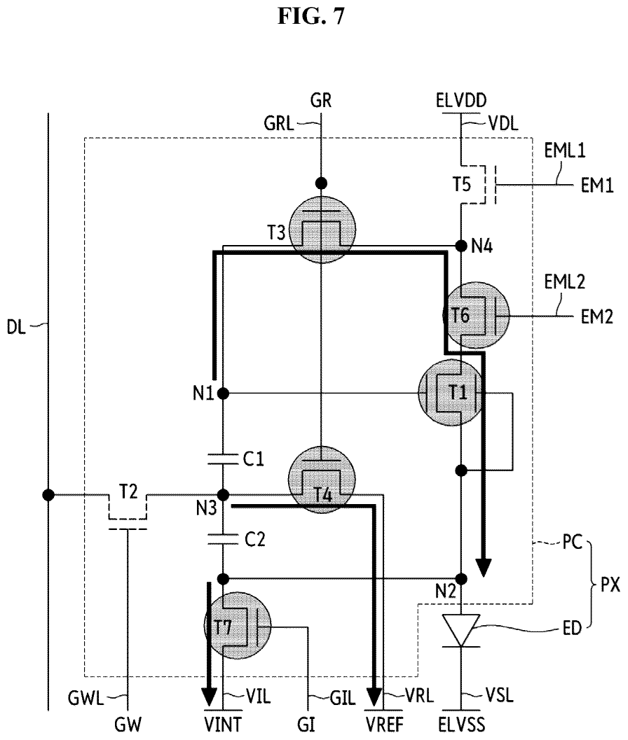

Next, an operation of the display device 100 in the second section P2 of the address scan section ADS is described as follows with reference to FIGS. 4 and 7.

FIG. 7 illustrates an operation of the display device 100 of FIG. 3 in the second section P2 of the address scan section ADS of FIG. 4.

In the second section P2, a reset gate signal GR of an active level may be applied to the gate electrode of the third transistor T3 and the gate electrode of the fourth transistor T4, respectively, through the reset gate line GRL. Accordingly, the third transistor T3 and the fourth transistor T4 may each be turned on.

In the second section P2, a second emission control signal EM2 of an active level may be applied to the gate electrode of the sixth transistor T6 through the second emission control line EML2. Accordingly, the sixth transistor T6 may be turned on.

In the second section P2, an initialization gate signal GI of an active level may be applied to the gate electrode of the seventh transistor T7 through the initialization gate line GIL. Accordingly, the seventh transistor T7 may be turned on.

In the second section P2, a write gate signal GW of a non-active level may be applied to the gate electrode of the second transistor T2 through the write gate line GWL. Accordingly, the second transistor T2 may be turned off.

In the second section P2, a first emission control signal EM1 of a non-active level may be applied to the gate electrode of the fifth transistor T5 through the first emission control line EML1. Accordingly, the fifth transistor T5 may be turned off.

As described above, as the fifth transistor T5 is turned off, an electrical connection between the driving voltage line VDL and the fourth node N4 may be disconnected.

As described above, as the third transistor T3 and the sixth transistor T6 are each turned on, the first node N1, the fourth node N4, and the drain electrode of the first transistor T1 may be electrically connected. Accordingly, the gate electrode of the first transistor T1 may be electrically connected to the drain electrode of the first transistor T1. For example, the first transistor T1 may be connected to the first node N1 and the fourth node N4 in the form of a diode.

The first transistor T1 may be turned on by the driving voltage ELVDD applied in the previous section (e.g., the first section P1). However, as charges of the first node N1 and the fourth node N4 flow through the turned-on sixth transistor T6, the turned-on first transistor T1, and the turned-on seventh transistor T7, the voltage of the first node N1 and the voltage of the fourth node N4 begin to gradually decrease. Therefore, the first transistor T1 may be turned off at the moment when the voltage of the first node N1 and the voltage of the second node N2 reach the threshold voltage of the first transistor T1. For example, as the voltage of the first node N1 connected to the gate electrode of the first transistor T1 gradually decreases, whereas the voltage of the second node N2 connected to the source electrode of the first transistor T1 is maintained at the initialization voltage VINT, a differential voltage between the gate electrode and the source electrode of the first transistor T1 (e.g., a gate-source voltage of the first transistor T1) may gradually decrease. Therefore, the first transistor T1 may be turned off at the moment when the gate-source voltage of the first transistor T1 becomes equal to the threshold voltage of the first transistor T1. In this case, the threshold voltage of the first transistor T1 may be detected, and the detected threshold voltage of the first transistor T1 may be stored (or maintained) by the first capacitor C1 and the second capacitor C2.

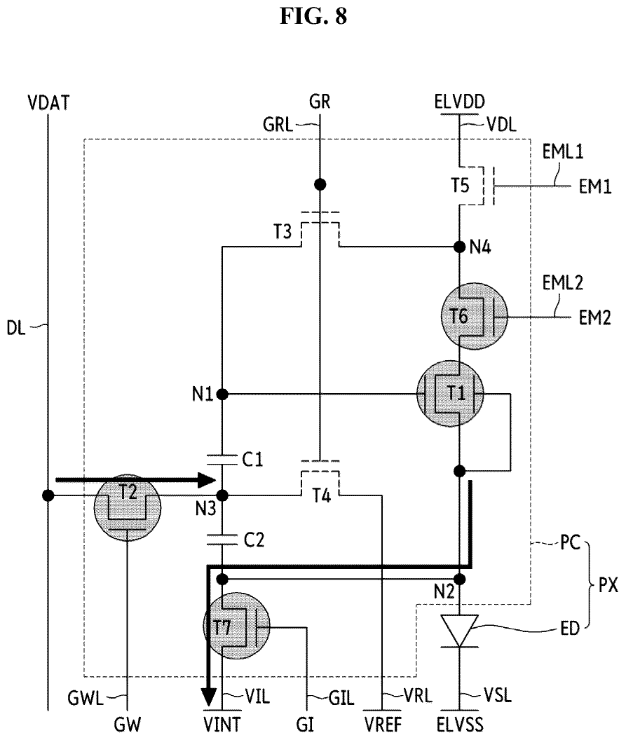

Next, an operation of the display device 100 in the third section P3 of the address scan section ADS is described as follows with reference to FIGS. 4 and 8.

FIG. 8 illustrates an operation of the display device 100 of FIG. 3 in the third section P3 of the address scan section ADS of FIG. 4.

In the third section P3, a write gate signal GW of an active level may be applied to the gate electrode of the second transistor T2 through the write gate line GWL. Accordingly, the second transistor T2 may be turned on.

In the third section P3, a second emission control signal EM2 of an active level may be applied to the gate electrode of the sixth transistor T6 through the second emission control line EML2. Accordingly, the sixth transistor T6 may be turned on.

In the third section P3, an initialization gate signal GI of an active level may be applied to the gate electrode of the seventh transistor T7 through the initialization gate line GIL. Accordingly, the seventh transistor T7 may be turned on.

In the third section P3, a reset gate signal GR of a non-active level may be applied to the gate electrode of the third transistor T3 and the gate electrode of the fourth transistor T4, respectively, through the reset gate line GRL. Accordingly, the third transistor T3 and the fourth transistor T4 may each be turned off.

In the third section P3, a first emission control signal EM1 of a non-active level may be applied to the gate electrode of the fifth transistor T5 through the first emission control line EML1. Accordingly, the fifth transistor T5 may be turned off.

As described above, as the third transistor T3 is turned off, the first node N1 may be floated.

As described above, as the second transistor T2 is turned on, a data voltage VDAT from the data line DL may be applied to the third node N3. In this case, the data voltage VDAT applied to the third node N3 may be divided by the first capacitor C1 and the second capacitor C2 and reflected to the first node N1 (e.g., the floated first node N1). For example, the magnitude of the data voltage added to the voltage of the first node N1 may be determined by the ratio of the capacitance of the first capacitor C1 and the capacitance of the second capacitor C2. According to an embodiment, the voltage added to the first node N1 may be determined by “(capacitance of C1/(capacitance of C1+capacitance of C2))”.

As described above, as the voltage of the first node N1 increases due to the data voltage VDAT, the first transistor T1 connected to the first node N1 through the gate electrode may be turned on. In this case, the threshold voltage of the first transistor T1 described above may be reflected to the voltage of the first node N1. Accordingly, a voltage to which the data voltage VDAT and the threshold voltage of the first transistor T1 are reflected may be applied to the gate electrode of the first transistor T1.

As described above, as the sixth transistor T6, the first transistor T1, and the seventh transistor T7 are turned on, the voltage of the second node N2 may be initialized to the initialization voltage VINT. Here, the initialization voltage VINT may have a magnitude close to a black gradation. Therefore, the voltage of the second node N2 may have a voltage close to a level of the black gradation. Accordingly, in the third section P3, the voltage of the second node N2 may be maintained at a low voltage. As the voltage of the second node N2 is maintained to be low at the same voltage as the initialization voltage VINT in the third section P3, the light emitting element ED may be turned off at a sufficiently fast speed in the next section (e.g., the fourth section P4) even when the gradation of the data voltage VDAT rapidly changes from a white gradation to a black gradation. Therefore, even when an image rapidly changes from the white gradation to the black gradation, the image corresponding to the black gradation may be accurately expressed.

In addition, a voltage fluctuation rate of the second node N2 may be minimized through the first capacitor C1 and the second capacitor C2. Therefore, a luminance deviation of the light emitting element ED in adjacent light emitting sections (e.g., P4) having a large gradation difference may be minimized.

In addition, since the first capacitor C1 in which the threshold voltage of the first transistor T1 is stored and the source electrode of the first transistor T1 (e.g., the second node N2) are separated from each other by the second capacitor C2, a fluctuation rate of the threshold voltage of the first transistor T1 (e.g., the threshold voltage of the first transistor T1 stored in the first capacitor C1) when the data voltage VDAT is input in the second section P2 may be minimized. In other words, a compensation error of the threshold voltage may be removed. For example, when the data voltage VDAT is input, the above-described compensation error may be improved by removing a charging path of the first capacitor C1 through the first transistor T1.

In addition, since the first capacitor C1 and the second capacitor C2 are connected in series between the gate electrode of the first transistor T1 (e.g., the first node N1) and the source electrode of the first transistor T1 (e.g., the second node N2), a transmission rate of the data voltage VDAT may be increased. Accordingly, power consumption of the display device 100 may be reduced.

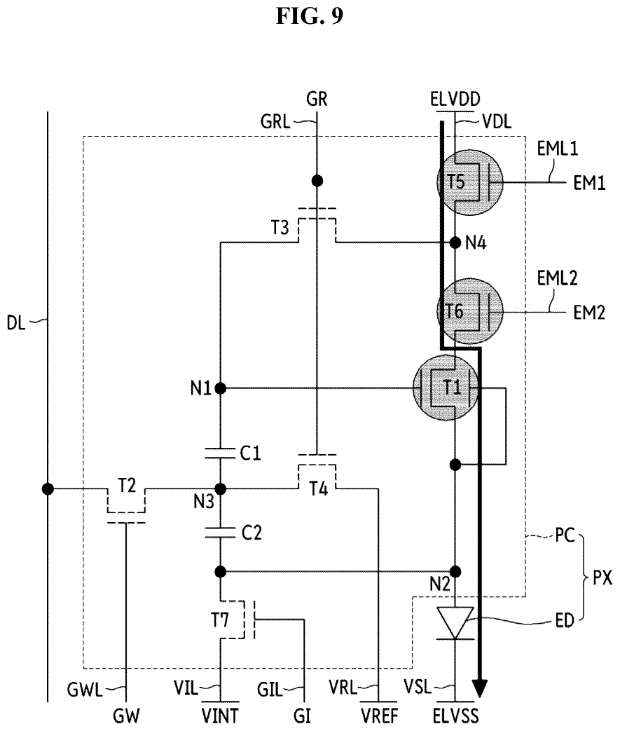

Next, an operation of the display device 100 in the fourth section P4 of the address scan section ADS is described as follows with reference to FIGS. 4 and 9.

FIG. 9 illustrates an operation of the display device 100 of FIG. 3 in the fourth section P4 of the address scan section ADS of FIG. 4.

In the fourth section P4, the first transistor T1 may be maintained in the turned-off state by the data voltage input in the previous section (e.g., the third section P3).

In the fourth section P4, a first emission control signal EM1 of an active level may be applied to the gate electrode of the fifth transistor T5 through the first emission control line EML1. Accordingly, the fifth transistor T5 may be turned on.

In the fourth section P4, a second emission control signal EM2 of an active level may be applied to the gate electrode of the sixth transistor T6 through the second emission control line EML2. Accordingly, the sixth transistor T6 may be turned on.

In the fourth section P4, a write gate signal GW of a non-active level may be applied to the gate electrode of the second transistor T2 through the write gate line GWL. Accordingly, the second transistor T2 may be turned off.

In the fourth section P4, a reset gate signal GR of a non-active level may be applied to the gate electrode of the third transistor T3 and the gate electrode of the fourth transistor T4, respectively, through the reset gate line GRL. Accordingly, the third transistor T3 and the fourth transistor T4 may each be turned off.

In the fourth section P4, an initialization gate signal GI of a non-active level may be applied to the gate electrode of the seventh transistor T7 through the initialization gate line GIL. Accordingly, the seventh transistor T7 may be turned off.

As described above, as the fifth transistor T5, the sixth transistor T6, and the first transistor T1 are turned on, the driving current may be supplied to the light emitting element ED through the fifth transistor T5, the sixth transistor T6, and the first transistor T1 that are turned on. Therefore, the light emitting element ED may emit light depending on the driving current. In this case, since the gate-source voltage of the first transistor T1 maintained by the first capacitor C1 and the second capacitor C2 includes the threshold voltage of the first transistor T1, the magnitude of the driving current flowing to the light emitting element ED through the turned-on first transistor T1 may be determined based on the data voltage and the threshold voltage of the first transistor T1. Therefore, the driving current supplied to the light emitting element ED may accurately reflect the magnitude of the data voltage. In this way, since the threshold voltages having different values of the first transistors T1 of each pixel PX are compensated to determine the driving current of each pixel PX, a luminance deviation between the pixels PX due to a deviation in threshold voltage between the first transistors T1 of each pixel PX may be minimized. Therefore, an image quality of the display device 100 may be improved.

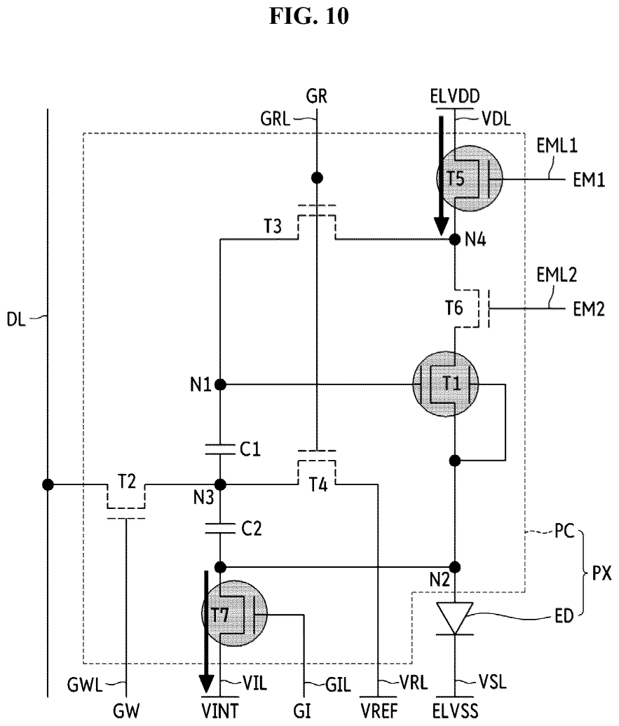

Next, an operation of the display device 100 in the fifth section P5 of the self-scan section SFS is described as follows with reference to FIGS. 5 and 10.

FIG. 10 illustrates an operation of the display device 100 of FIG. 3 in the fifth section P5 of the self-scan section SFS of FIG. 5.

In the fifth section P5, a first emission control signal EM1 of an active level may be applied to the gate electrode of the fifth transistor T5 through the first emission control line EML1. Accordingly, the fifth transistor T5 may be turned on.

In the fifth section P5, an initialization gate signal GI of an active level may be applied to the gate electrode of the seventh transistor T7 through the initialization gate line GIL. Accordingly, the seventh transistor T7 may be turned on.

In the fifth section P5, a write gate signal GW of a non-active level may be applied to the gate electrode of the second transistor T2 through the write gate line GWL. Accordingly, the second transistor T2 may be turned off.

In the fifth section P5, a reset gate signal GR of a non-active level may be applied to the gate electrode of the third transistor T3 and the gate electrode of the fourth transistor T4, respectively, through the reset gate line GRL. Accordingly, the third transistor T3 and the fourth transistor T4 may each be turned off.

In the fifth section P5, a second emission control signal EM2 of a non-active level may be applied to the gate electrode of the sixth transistor T6 through the second emission control line EML2. Accordingly, the sixth transistor T6 may be turned off.

As described above, as the fifth transistor T5 is turned on, the voltage of the fourth node N4 may be initialized to the driving voltage ELVDD.

As described above, as the seventh transistor T7 is turned on, the voltage of the second node N2 may be initialized to the initialization voltage VINT.

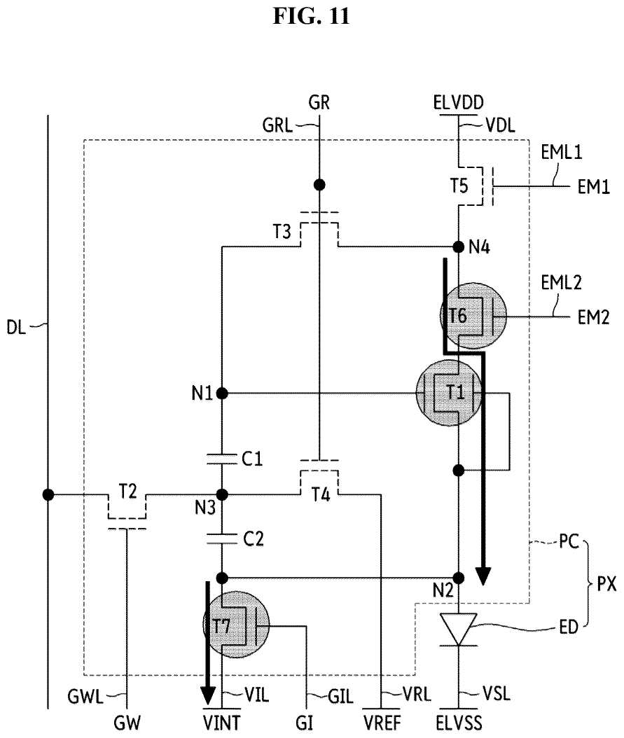

Next, an operation of the display device 100 in the sixth section P6 of the self-scan section SFS is described as follows with reference to FIGS. 5 and 11.

FIG. 11 illustrates an operation of the display device 100 of FIG. 3 in the sixth section P6 of the self-scan section SFS of FIG. 5.

In the sixth section P6, a second emission control signal EM2 of an active level may be applied to the gate electrode of the sixth transistor T6 through the second emission control line EML2. Accordingly, the sixth transistor T6 may be turned on.

In the sixth section P6, an initialization gate signal GI of an active level may be applied to the gate electrode of the seventh transistor T7 through the initialization gate line GIL. Accordingly, the seventh transistor T7 may be turned on.

In the sixth section P6, a write gate signal GW of a non-active level may be applied to the gate electrode of the second transistor T2 through the write gate line GWL. Accordingly, the second transistor T2 may be turned off.

In the sixth section P6, a reset gate signal GR of a non-active level may be applied to the gate electrode of the third transistor T3 and the gate electrode of the fourth transistor T4, respectively, through the reset gate line GRL. Accordingly, the third transistor T3 and the fourth transistor T4 may each be turned off.

In the sixth section P6, a first emission control signal EM1 of a non-active level may be applied to the gate electrode of the fifth transistor T5 through the first emission control line EML1. Accordingly, the fifth transistor T5 may be turned off.

As described above, as the sixth transistor T6 and the seventh transistor T7 are turned on, the voltage of the second node N2 may be initialized to the initialization voltage VINT through the sixth transistor T6 and the seventh transistor T7 that are turned on and the turned-on first transistor T1.

Next, an operation of the display device 100 in the seventh section P7 of the self-scan section SFS is described as follows.

Since the operation in the seventh section P7 of the self-scan section SFS is substantially the same as the operation in the fourth section P4 of the address scan section ADS described above, the operation of the display device in the seventh section P7 refers to the above-described FIG. 9 and the related description.

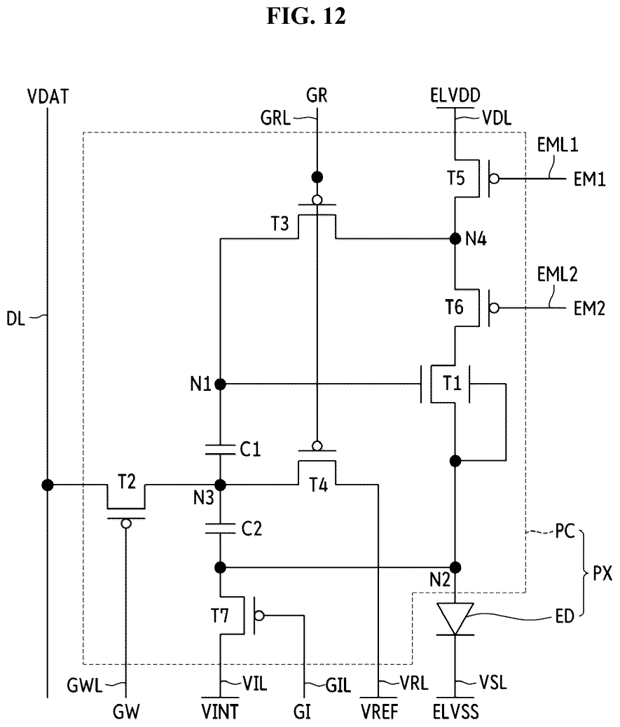

FIG. 12 is a circuit diagram of a pixel PX according to an embodiment.

A pixel PX illustrated in FIG. 12 differs from the pixel PX of FIG. 3 described above in that the second to seventh transistors T2 to T7 are each p-type transistors. This difference will be specifically described as follows.

As illustrated in FIG. 12, each of the second to seventh transistors T2 to T7 may be a p-type transistor. In this case, a first emission control signal EM1, a second emission control signal EM2, a reset gate signal GR, a write gate signal GW, and an initialization gate signal GI provided to the pixel PX of FIG. 12 may have a phase inverted by 180 degrees with respect to the first emission control signal EM1, the second emission control signal EM2, the reset gate signal GR, the write gate signal GW, and the initialization gate signal GI of FIGS. 4 and 5, respectively.

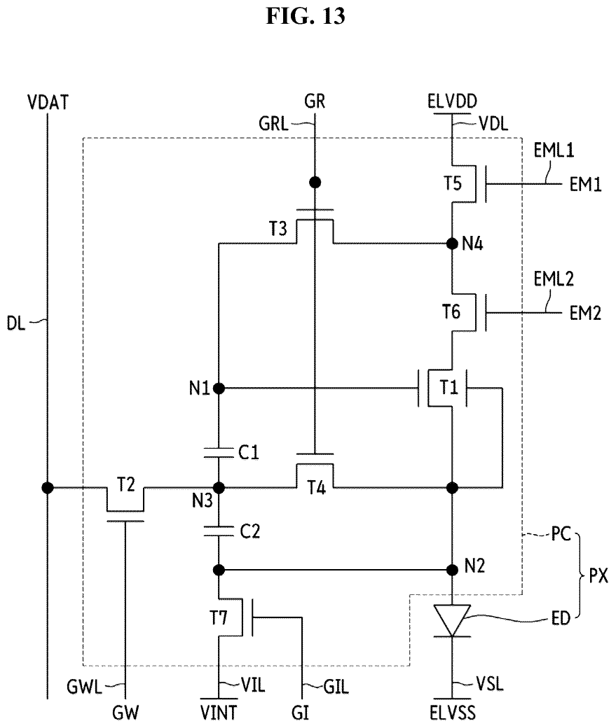

FIG. 13 is a circuit diagram of a pixel PX according to an embodiment.

A pixel PX illustrated in FIG. 13 differs from the pixel PX of FIG. 3 described above in terms of the connection relationship of the fourth transistor T4. This difference will be specifically described as follows.

As illustrated in FIG. 13, the fourth transistor T4 may be connected between the third node N3 and the second node N2. For example, the gate electrode of the fourth transistor T4 may be electrically connected to the reset gate line GRL, the drain electrode of the fourth transistor T4 may be electrically connected to the third node N3, and the source electrode of the fourth transistor T4 may be electrically connected to the second node N2. In this case, the reference voltage line VRL and the reference voltage VREF may be omitted.

The display device 100 according to the embodiment may be applied to various electronic devices. An electronic device according to an embodiment may include the display device 100 described above, and may further include a module or device having additional functions in addition to the display device 100.

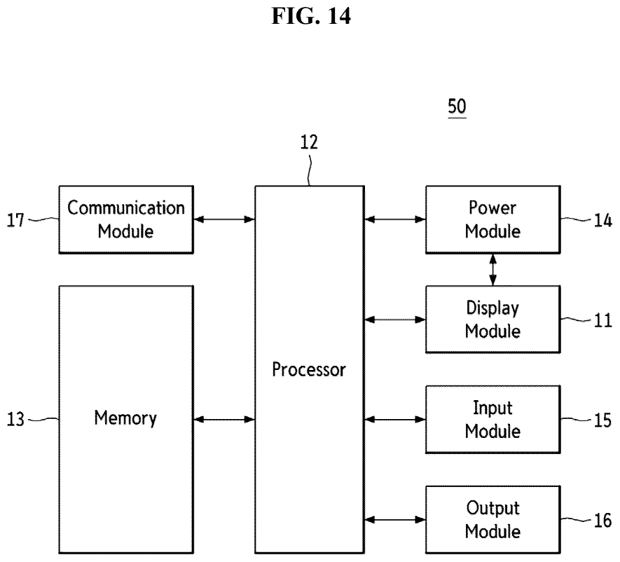

FIG. 14 illustrates an electronic device according to an embodiment. Referring to FIG. 14, an electronic device 50 according to an embodiment may include a display module 11, a processor 12, a memory 13, and a power module 14. The electronic device 50 may further include an input module 15, a non-image output module 16, and/or a communication module 17.

The electronic device 50 may output various information in the form of an image through the display module 11. When the processor 12 executes an application stored in the memory 13, image information provided by the application may be provided to the user through the display module 11. The power module 14 may include a power supply module, such as a power adapter or a battery device, and a power conversion module that converts power supplied by the power supply module to generate power required for an operation of the electronic device 50. The input module 15 may provide input information to the processor 12 and/or the display module 11. The non-image output module 16 may serve to receive information other than the image received from the processor 12, such as sound, haptics, and light emission, and provide the information to the user. The communication module 17 is a module responsible for transmitting and receiving information between the electronic device 50 and an external device, and may include a receiving unit and a transmitting unit.

At least one of the components of the electronic device 50 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 50 other than the display device.

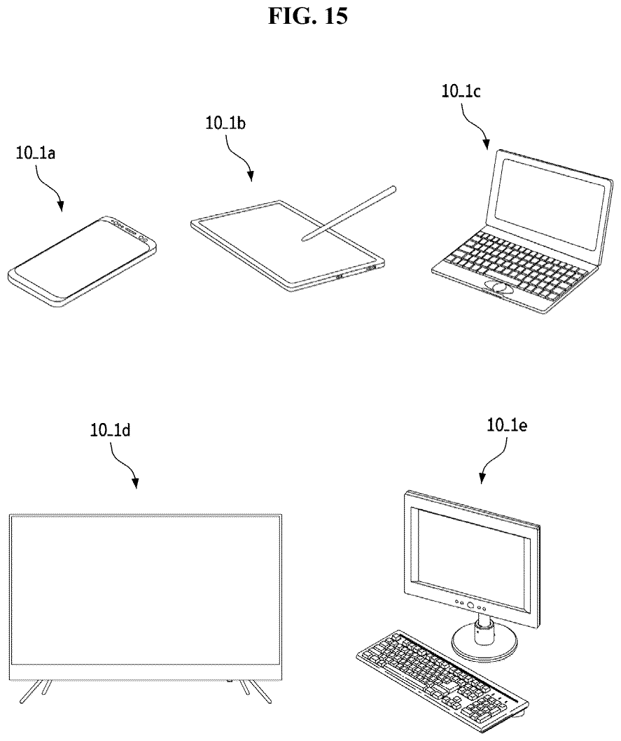

FIGS. 15, 16, and 17 illustrate electronic devices according to various embodiments. FIGS. 15, 16, and 17 illustrate examples of electronic devices to which the display device 100 according to the embodiments is applied.

FIG. 15 illustrates examples of the electronic devices, including a smartphone 10_1a, a tablet PC 10_1b, a laptop 10_1c, a TV 10_1d, and a desk monitor 10_1e.

The smartphone 10_1a may include an input module such as a touch sensor and a communication module in addition to the display module 11. The smartphone 10_1a may process information received through the communication module or other input modules and display the information through the display module of the display device.

The tablet PC 10_1b, the laptop 10_1c, the TV 10_1d, and the desk monitor 10_1e also include a display module and an input module similarly to the smartphone 10_1a, and in some cases, may further include a communication module.

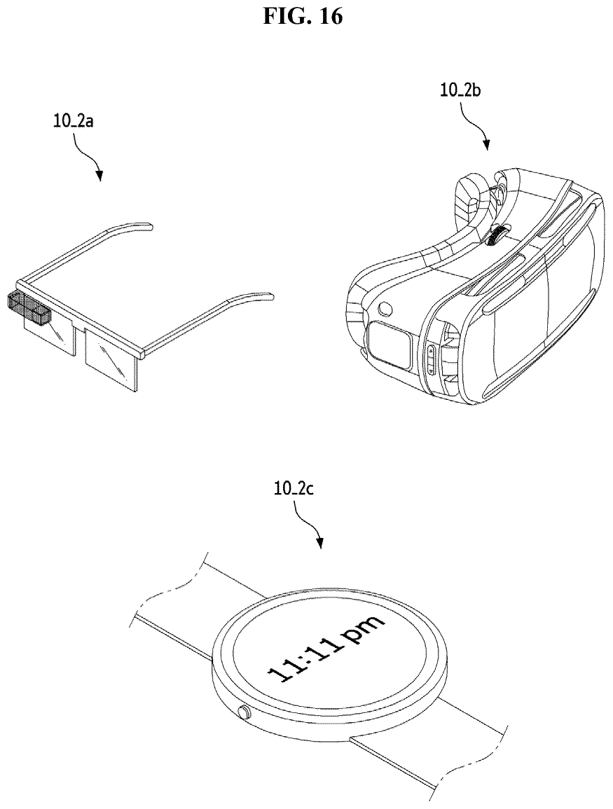

FIG. 16 illustrates a case in which an electronic device including a display module is applied to a wearable electronic device. The wearable electronic device may be a smart glasses 10_2a, a head mounted display 10_2b, a smart watch 10_2c, etc.

The smart glasses 10_2a and the head mounted display 10_2b may include a display module that emits a display image and a reflector that reflects the emitted display image and provides the reflected display image to the user's eyes, and may provide the user with a virtual reality or augmented reality screen through the display module and the reflector.

The smart watch 10_2c includes a biometric sensor as an input device and may provide the biometric information recognized by the biometric sensor to the user through the display module.

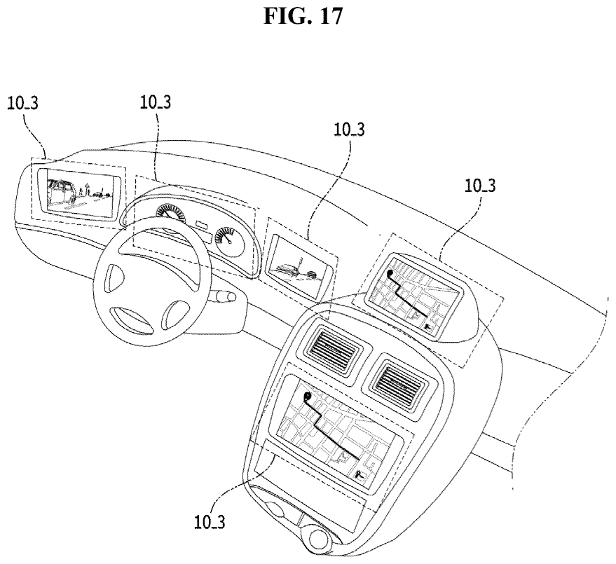

FIG. 17 illustrates an example in which an electronic device including a display module is applied to a vehicle. For example, an electronic device 10_3 may be applied to a dashboard, center fascia, etc. of an automobile, or may be applied to a Center Information Display (CID) disposed on the dashboard of the automobile or a room mirror display replacing a side mirror.

Those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A display device comprising a display panel in which a pixel is disposed, wherein the pixel comprises:
a light emitting element connected between a driving voltage line and a common voltage line;
a first transistor connected between the driving voltage line and an anode electrode of the light emitting element;
a second transistor connected between a data line and a first node;
a first capacitor connected between a gate electrode of the first transistor and the first node; and
a second capacitor connected between the first node and the anode electrode of the light emitting element.

2. The display device of claim 1, wherein the pixel further comprises:
a third transistor connected between the gate electrode of the first transistor and a second node;
a fourth transistor connected between the first node and a reference voltage line;
a fifth transistor connected between the driving voltage line and the second node;
a sixth transistor connected between the second node and a drain electrode of the first transistor; and
a seventh transistor connected between the anode electrode of the light emitting element and an initialization voltage line.

3. The display device of claim 2, further comprising:
a write gate line connected to a gate electrode of the second transistor;
a reset gate line connected to a gate electrode of the third transistor and a gate electrode of the fourth transistor;
a first emission control line connected to a gate line of the fifth transistor;
a second emission control line connected to a gate line of the sixth transistor; and
an initialization gate line connected to a gate electrode of the seventh transistor.

4. The display device of claim 3, wherein the write gate line transmits a write gate signal,
the reset gate line transmits a reset gate signal,
the first emission control line transmits a first emission control signal,
the second emission control line transmits a second emission control signal, and
the initialization gate line transmits an initialization gate signal.

5. The display device of claim 4, wherein, in a first section of an address scan section,
the first emission control signal, the reset gate signal, and the initialization gate signal each have an active level, and
the second emission control signal and the write gate signal each have a non-active level.

6. The display device of claim 4, wherein, in a second section of an address scan section,
the second emission control signal, the reset gate signal, and the initialization gate signal each have an active level, and
the first emission control signal and the write gate signal each have a non-active level.

7. The display device of claim 4, wherein, in a third section of an address scan section,
the second emission control signal, the write gate signal, and the initialization gate signal each have an active level,
the first emission control signal and the reset gate signal each have a non-active level, and
a data voltage is applied to the data line.

8. The display device of claim 4, wherein, in a fourth section of an address scan section,
the first emission control signal and the second emission control signal each have an active level, and
the reset gate signal and the initialization gate signal each have a non-active voltage.

9. The display device of claim 4, wherein, in a fifth section of a self-scan section,
the first emission control signal and the initialization gate signal each have an active level, and
the second emission control signal, the reset gate signal, and the write gate signal each have a non-active level.

10. The display device of claim 4, wherein, in a sixth section of a self-scan section,
the second emission control signal and the initialization gate signal each have an active level, and
the first emission control signal, the reset gate signal, and the write gate signal each have a non-active level.

11. The display device of claim 4, wherein, in a seventh section of a self-scan section,
the first emission control signal and the second emission control signal each have an active level, and
the reset gate signal, the write gate signal, and the initialization gate signal each have a non-active voltage.

12. The display device of claim 3, further comprising an additional pixel disposed in the display panel and driven before the pixel,
wherein a gate electrode of the sixth transistor of the pixel and a gate electrode of a fifth transistor of the additional pixel are connected to the second emission control line.

13. The display device of claim 1, wherein the pixel further comprises:
a third transistor connected between the gate electrode of the first transistor and a second node;
a fourth transistor connected between the first node and electrode reference voltage;
a fifth transistor connected between the driving voltage line and the second node;
a sixth transistor connected between the second node and a drain electrode of the first transistor; and
a seventh transistor connected between the anode electrode of the light emitting element and an initialization voltage line.

14. The display device of claim 2, wherein the first transistor, the second transistor, the third transistor, the fourth transistor, the fifth transistor, the sixth transistor, and the seventh transistor are each n-type transistors.

15. The display device of claim 2, wherein the first transistor is an n-type transistor, and
the second transistor, the third transistor, the fourth transistor, the fifth transistor, the sixth transistor, and the seventh transistor are each p-type transistors.

16. An electronic device comprising a display device,
wherein the display device comprises a display panel in which a pixel is disposed, and wherein the pixel comprises:
a light emitting element connected between a driving voltage line and a common voltage line;
a first transistor connected between the driving voltage line and an anode electrode of the light emitting element;
a second transistor connected between a data line and a first node;
a first capacitor connected between a gate electrode of the first transistor and the first node; and
a second capacitor connected between the first node and the anode electrode of the light emitting element.

17. The electronic device of claim 16, wherein the pixel further comprises:
a third transistor connected between the gate electrode of the first transistor and a second node;
a fourth transistor connected between the first node and a reference voltage line;
a fifth transistor connected between the driving voltage line and the second node;
a sixth transistor connected between the second node and a drain electrode of the first transistor; and
a seventh transistor connected between the anode electrode of the light emitting element and an initialization voltage line.

18. The electronic device of claim 17, further comprising:
a write gate line connected to a gate electrode of the second transistor;
a reset gate line connected to a gate electrode of the third transistor and a gate electrode of the fourth transistor;
a first emission control line connected to a gate line of the fifth transistor;
a second emission control line connected to a gate line of the sixth transistor; and
an initialization gate line connected to a gate electrode of the seventh transistor.

19. The electronic device of claim 18, wherein the write gate line transmits a write gate signal,
the reset gate line transmits a reset gate signal,
the first emission control line transmits a first emission control signal,
the second emission control line transmits a second emission control signal, and
the initialization gate line transmits an initialization gate signal.

20. The electronic device of claim 16, wherein the electronic device correspond to at least one of a smartphone, a tablet, a laptop, a television (TV), a desk monitor, a smart glasses, a smart watch, a head mounted display, or a vehicle.
